(19) United States
(12) Patent Application Publication
(10) Pub. No.: US 2017/0039968 A1
(43) Pub. Date: Feb. 9, 2017

(54) SHIFT REGISTER, GATE DRIVING CIRCUIT, DISPLAY APPARATUS AND GATE DRIVING METHOD

(71) Applicants: BOE TECHNOLOGY GROUP CO., LTD., Beijing (CN); BEIJING BOE DISPLAY TECHNOLOGY CO., LTD., Beijing (CN)

(72) Inventors: Huabin CHEN, Beijing (CN); Bin FENG, Beijing (CN); Jianfeng YUAN, Beijing (CN)

(21) Appl. No.: 14/908,703

(22) PCT Filed: Aug. 19, 2015
(86) PCT No.: PCT/CN2015/087509

§ 371 Date: Jan. 29, 2016

(30) Foreign Application Priority Data
Mar. 27, 2015 (CN) 201510142625.6

(51) Int. Cl. G09G 3/36; G11C 19/28

(52) U.S. Cl. CPC G09G 3/3648; G11C 19/28; G09G 2300/0426; G09G 2310/0286; G09G 2310/08; G09G 2320/0209

(57) ABSTRACT

The present invention provides a shift register comprising a gate driving signal generation unit, a plurality of signal output control modules, a plurality of signal output reset modules and a plurality of signal output terminals. One terminal of each signal output control module is connected with the gate driving signal generation unit and the other terminal thereof is connected with one corresponding signal output terminal, and each signal output control module also has a respective control signal input terminal for outputting the gate driving signal outputted by the gate driving signal generation unit through the corresponding signal output terminal under control of a control signal inputted from the control signal input terminal, and one terminal of each signal output reset module is connected between the corresponding signal output control module and the corresponding signal output terminal for resetting output signal of the signal output terminal connected thereto.

### FIELD OF THE INVENTION

The present invention relates to the field of display technology, and particularly relates to a shift register, a gate driving circuit, a display apparatus and a gate driving method.

### BACKGROUND OF THE INVENTION

The basic principle of thin film transistor liquid crystal display (TFT-LCD) to realize display of a frame of picture is to perform gating on square waves with a certain width, which are inputted by each row of pixels, from top to bottom successively by gate driving, and then perform outputting for signals of each row of pixels from top to bottom successively by source driving. Currently, a display device with such a structure is usually obtained by manufacturing a gate driving circuit and a source driving circuit through a chip-on-film (COF) or a chip-on-glass (COG) process on a glass substrate. However, when there is a high resolution, both outputs from the gate driving circuit and outputs from the source driving circuit are quite a lot, a length of the driving circuit will be increased, resulting in that it becomes difficult to perform bonding on module driving circuit.

In order to overcome above problem, there is an existing display device manufactured by using a gate-drive-on-array (GOA) circuit design. Compared with the COF or COG process in the prior art, the gate-drive-on-array (GOA) circuit design can reduce the cost and can achieve an aesthetic design in which both sides of a panel are symmetric, and an area for boning of the gate driving circuit and a peripheral wiring space can also be leaved out, thereby achieving a narrow border design of a display apparatus, and improving productivity and yield of the display apparatus. However, there are also some problems in the GOA circuit design of prior art, as shown in FIG. 1, there are a large number of thin film transistors (TFTs) (e.g., M1-M6˜M8-M11) in each shift register of the GOA circuit of prior art, and each shift register only drives one row of gate line, thus a large space will be occupied. However, in order to really achieve a narrow border design of a display apparatus, it is necessary to further reduce the occupied space of the GOA circuit.

### SUMMARY OF THE INVENTION

In view of above problems existing in the gate driving circuit of prior art, the present invention provides a shift register, a gate driving circuit, a display apparatus and a gate driving method which can achieve a narrow border design.

As a first aspect, a technical solution of the present invention is to provide a shift register comprising a gate driving signal generation unit for outputting a gate driving signal, the shift register further comprises a plurality of signal output control modules, a plurality of signal output reset modules and a plurality of signal output terminals, wherein
one terminal of each of the signal output control modules is connected with the gate driving signal generation unit and the other terminal thereof is connected with one corresponding signal output terminal, and each of the signal output control modules also has a respective control signal input terminal for outputting the gate driving signal outputted by the gate driving signal generation unit through the corresponding signal output terminal under control of a control signal inputted from the control signal input terminal,
one terminal of each of the signal output reset: modules is connected between the corresponding signal output control module and the corresponding signal output terminal for resetting output signal of the signal output terminal connected thereto.

Preferably, each of the signal output control modules comprises one switch transistor, a first electrode of the switch transistor is connected with the gate driving signal generation unit, a second electrode of the switch transistor is connected with the corresponding signal output terminal and the corresponding signal output reset module, and a control electrode of the switch transistor is connected with the control signal input terminal.

Preferably, each of the signal output reset modules comprises one fourth transistor, a first electrode of the fourth transistor is connected between the corresponding signal output control module and the corresponding signal output terminal, a second electrode of the fourth transistor is connected with a low voltage signal, and a control electrode of the fourth transistor is connected with a reset signal input terminal.

Preferably, the shift register further comprises a plurality of output noise reduction modules,
one terminal of each of the output noise reduction modules is connected between the corresponding signal output control module and the corresponding signal output terminal for reducing noise of output signal of the signal output terminal connected thereto.

Further preferably, each of the output noise reduction modules comprises one eleventh transistor, a first electrode of the eleventh transistor is connected between the corresponding signal output control module and the corresponding signal output terminal, a second electrode of the eleventh transistor is connected with the low voltage signal, and a control electrode of the eleventh transistor is connected with a pull-down node of the gate driving signal generation unit.

Preferably, the gate driving signal generation unit comprises: an input module, a pull-up module, an input reset module, a pull-down control module, a pull-down module and an input noise reduction module, wherein,
the input module is connected between a signal input terminal and a pull-up control node of the shift register for controlling potential of the pull-up control node in accordance with a signal inputted from the signal input terminal, the pull-up control node is a connection node between the input module and the pull-up module,
the pull-up module is connected between the pull-up control node and the signal output control modules, a control terminal of the pull-up module is connected with a first clock signal input terminal for pulling up the gate driving signal to be outputted to the signal output terminal in accordance with the potential of the pull-up control node and a first clock signal inputted from the first clock signal input terminal,
one terminal of the input reset module is connected with the pull-up control node, and a control terminal of the input reset module is connected with the reset signal input terminal for pulling down and resetting the potential of the pull-up control node in accordance with a reset signal inputted from the reset signal input terminal,
one terminal of the pull-down control module is connected with the pull-down node, and a control terminal of the pull-down control module is connected with a second clock signal input terminal for controlling potential of the pull-down node in accordance with a second clock signal inputted from the second clock signal input terminal, the pull-down node is a connection node between the pull-down control module and the pull-down module,
the pull-down module is connected between the pull-down node and the pull-up control node for pulling down the potential of the pull-down node under control of potential of the pull-up control node,
the input noise reduction module is connected between the pull-up control node and the pull-down node for reducing output noise at the pull-up control node under control of potential of the pull-down node.

Further preferably, the input module comprises a first transistor, the input reset module comprises a second transistor, the pull-up module comprises a third transistor and a storage capacitor, the pull-down control module comprises a fifth transistor and a ninth transistor, the pull-down module comprises a sixth transistor and an eighth transistor, the input noise reduction module comprises a tenth transistor, wherein
a first electrode and a control electrode of the first transistor are connected with the signal input terminal of the shift register, a second electrode of the first transistor is connected with the pull-up control node,
a first electrode of the second transistor is connected with the pull-up control node, a second electrode of the second transistor is connected with the low voltage signal, and a control electrode of the second transistor is connected with the reset signal input terminal,
a first electrode of the third transistor is connected with the first clock signal input terminal, a second electrode of the third transistor is connected with a second terminal of the storage capacitor and the signal output control modules, a control electrode of the third transistor is connected with the pull-up control node and a first terminal of the storage capacitor,
a first electrode of the fifth transistor and a first electrode and a control electrode of the ninth transistor are connected with the second clock signal input terminal, a second electrode of the fifth transistor is connected with the pull-down node, and a control electrode of the fifth transistor is connected with a second electrode of the ninth transistor,
a first electrode of the sixth transistor is connected with the pull-down node, second electrodes of the sixth transistor and the eighth transistor are connected with the low voltage signal, control electrodes of the sixth transistor and the eighth transistor are connected with the pull-up control node, a first electrode of the eighth transistor is connected with the control electrode of the fifth transistor and a second electrode of the ninth transistor,
a first electrode of the tenth transistor is connected with the pull-up control node, a second electrode of the tenth transistor is connected with the low voltage signal, and a control electrode of the tenth transistor is connected with the pull-down node.

Further preferably, each of the signal output control modules comprises one switch transistor, each of the signal output reset modules comprises one fourth transistor, each of the output noise reduction modules comprises one eleventh transistor, wherein
a first electrode of the switch transistor is connected with the second terminal of the storage capacitor, a second electrode of the switch transistor is connected with the corresponding signal output terminal, and a control electrode of the switch transistor is connected with the corresponding control signal input terminal,
a first electrode of the fourth transistor is connected between the corresponding signal output terminal and the second electrode of the switch transistor, a second electrode of the fourth transistor is connected e low voltage signal, and a control electrode of the fourth transistor is connected with the reset signal input terminal,
a first electrode of the eleventh transistor is connected between the second electrode of the corresponding switch transistor and the corresponding signal output terminal, a second electrode of the eleventh transistor is connected with the low voltage signal, and the control electrode of the eleventh transistor is connected with the pull-down node.

Preferably, the shift register comprises two signal output control modules, two signal output reset modules and two signal output terminals.

As a second aspect, a technical solution of the present invention is to provide a gate driving circuit comprises a plurality of above shift registers cascaded with each other,
a signal outputted by the gate driving signal generation unit of the shift register of each stage is used as an input signal of the signal input terminal of the shift register of next stage,
a signal outputted from each signal output terminal of the shift register of each stage is used for driving one gate line.

As a third aspect, a technical solution of the present invention is to provide a display apparatus comprising the gate driving circuit as above.

As a fourth aspect, a technical solution of the present invention is to provide a gate driving method comprising:
outputting a gate driving signal by a gate driving signal generation unit of a shift register in a gate driving circuit,
when a picture is to be displayed, outputting a plurality of gate driving signals from a plurality of signal output terminals of the shift register in a time-division manner by using respective signal output control modules connected to the signal output terminals, and resetting output signals of the signal output terminals by using respective signal output reset modules connected to the signal output terminals.

Preferably, the gate driving circuit comprises a plurality of shift registers cascaded with each other, and the gate driving method comprises driving one gate line by using a signal outputted from each signal output terminal of the shift register of each stage.

The present invention has following beneficial effects.

Since the shift register of the present invention has a plurality of signal output terminals, a plurality of signal output control modules and a plurality of signal output reset modules for controlling the signal output terminals to output signals, that is, each shift register of the present invention can drive a plurality of gate lines, thus when the shift register of the present invention is applied into a display panel, the number of the shift registers to be used in the display panel is reduced, so that the space to be occupied by the GOA circuit is further reduced, and a really narrow border design of a display apparatus can be achieved.

### BRIEF DESCRIPTION OF THE DRAWINGS

FIG. 1 is a circuit diagram of a shift register in the prior art;

FIG. 2 is a schematic diagram of a shift register of the present invention;

FIG. 3 is a schematic diagram of a preferred mode of a shift register of the present invention;

FIG. 4 is a schematic diagram of another preferred mode of a shift register of the present invention;

FIG. 5 is a circuit diagram of a shift register of embodiments of the present invention;

FIG. 6 is an operational timing diagram of a shift register of embodiments of the present invention.

### DETAILED DESCRIPTION OF THE EMBODIMENTS

In order to make persons skilled in the art better understand technical solutions of the present invention, detailed descriptions of the present invention will be provided below in conjunction with drawings and embodiments.

Transistors used in embodiments of the present invention may be thin film transistors, field effect transistors or similar devices with equivalent characteristics, which are not limited in the present invention. Since a source and a drain of a transistor are symmetrical, there is no difference therebetween. In embodiments of the present invention, to distinguish the source and the drain of the transistor, one electrode thereof is referred to as a first electrode, the other electrode thereof is referred to as a second electrode, and the gate is referred to as a control electrode. In addition, transistors may be divided into N type and P type according to characteristics of the transistors, and following embodiments are described by taking N type transistors as example. For example, when N type transistors are employed, the sources of the N type transistors are first electrodes, the drains of the N type transistors are second electrodes, and when a high level is inputted into the gates (i.e., control electrodes) thereof, the sources are electrically connected with the drains. Optionally, when P type transistors are employed, states of electrodes thereof are opposite to those of N type transistors. It should be understood that, it is conceivable for persons skilled in the art to employ P type transistors without any creative work, thus the implementations using P type transistors also fall into the protection scope of the present invention.

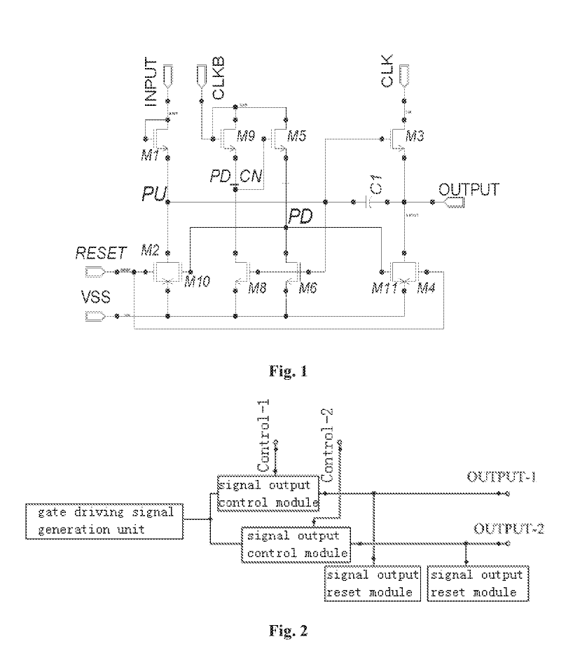

A shift register in accordance with an embodiment of the present invention is described with reference to FIG. 2.

As shown in FIG. 2, the shift register comprises a gate driving signal generation unit for outputting a gate driving signal, and comprises a plurality of signal output control modules, a plurality of signal output reset modules and a plurality of signal output terminals (OUTPUT-1, OUTPUT-2). FIG. 2 shows an example in which two signal output control modules, two signal output reset modules, and two signal output terminals are provided, but the present invention is not limited thereto, signal output lines of the present invention may be extended to more.

One terminal of each of the signal output control modules is connected with the gate driving signal generation unit and the other terminal thereof is connected with one corresponding signal output terminal, and each of the signal output control modules further has a respective control signal input terminal (Control-1, Control-2) for outputting the gate driving signal outputted by the gate driving signal generation unit through the corresponding signal output terminal (OUTPUT-1, OUTPUT-2) under control of a control signal inputted from the control signal input terminal (Control-1, Control-2). One terminal of each of the signal output reset modules is connected between the corresponding signal output control module and the corresponding signal output terminal for resetting output signal of the signal output terminal connected thereto.

Since the above shift register has the gate driving signal generation unit, the plurality of signal output control modules and the plurality of signal output reset modules, and has the plurality of signal output terminals, it should be understood that, each of the signal output terminals provides the gate driving signal to one gate line, thus each shift register can provide gate driving signals to a plurality of gate lines, and when the shift register is applied into a display panel, the number of the shift registers to be used in the display panel is reduced, so that the space to be occupied by the GOA circuit is further reduced, and a really narrow border design of a display apparatus can be achieved. Specific implementations of the shift register are described in following embodiments.

In a preferred embodiment, each of the signal output control modules comprises one switch transistor, a first electrode of the switch transistor is connected with the gate driving signal generation unit, a second electrode of the switch transistor is connected with the corresponding signal output terminal and the corresponding signal output reset module, and a control electrode of the switch transistor is connected with the control signal input terminal.

That is, each of the signal output control modules only comprises one switch transistor, the corresponding signal output terminal is controlled to output the gate driving signal or not by controlling the switch transistor to be turned on or turned off, such a structure of the signal output control module is simple and easily controlled, and the cost thereof is low.

In a preferred embodiment, each of the signal output reset modules comprises one fourth transistor, a first electrode of the fourth transistor is connected between the corresponding signal output control module and the corresponding signal output terminal, a second electrode of the fourth transistor is connected with a low voltage signal, and a control electrode of the fourth transistor is connected with a reset signal input terminal.

That is, each of the signal output reset module only comprises one fourth transistor, the signal outputted from the signal output terminal is reset by controlling the fourth transistor, such a structure of the signal output reset module is simple and easily controlled, and the cost thereof is low.

The shift register of the present invention is described below in conjunction with drawings and following preferred embodiment.

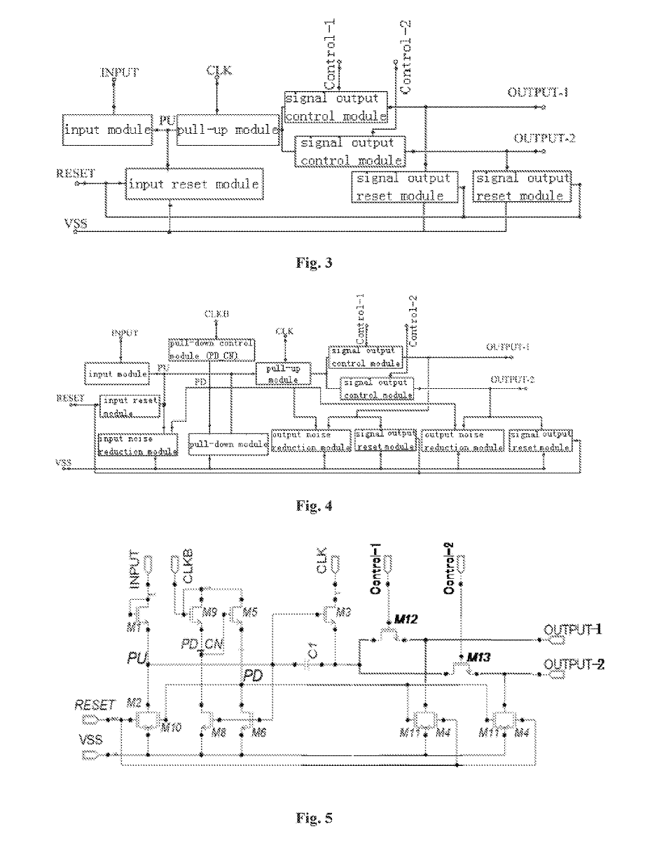

As shown in FIG. 3, the present embodiment provides a shift register comprising a gate driving signal generation unit, a plurality of signal output control modules, a plurality of signal output reset modules and a plurality of signal output terminals (OUTPUT-1, OUTPUT-2), wherein the gate driving signal generation unit in the present embodiment comprises an input module, a pull-up module, and an input reset module. In the present embodiment, the input module is connected between a signal input terminal INPUT and a pull-up control node PU of the shift register, for controlling electric potential of the pull-up control node PU in accordance with a signal inputted from the signal input terminal INPUT, and the pull-up control node PU is a connection node between the input module and the pull-up module. The pull-up module is connected between the pull-up control node PU and the signal output control modules, and a control terminal of the pull-up module is connected with a first clock signal input terminal CLK, for pulling up the gate driving signal to be outputted to the signal output terminal in accordance with the potential of the pull-up control node PU and the first clock signal inputted from the first clock signal input terminal CLK (that is, the gate driving signal is pulled up to be at a high level). One terminal of each of the signal output control modules is connected with the pull-up module, and the other terminal thereof is connected with one corresponding signal output terminal OUTPUT (N) (all of the signal output terminals are represented by OUTPUT (N)). Each of the signal output control modules is also connected with a respective control signal input terminal Control (N), for outputting the pulled-up gate driving signal outputted by the pull-up module through the corresponding signal output terminal OUTPUT (N) under control of a control signal inputted from the control signal input terminal Control (N). One terminal of the input reset module is connected with the pull-up control node PU, and a control terminal of the input reset module is connected with the reset signal input terminal RESET, for pulling down the potential of the pull-up control node PU in accordance with a reset signal inputted from the reset signal input terminal RESET (that is, the potential of the pull-up control node PU is pulled down to be at a low level), and in the present embodiment, the other terminal of the input reset module is connected with a low voltage signal VSS. One terminal of each of the signal output reset module is connected between the corresponding signal output terminal OUTPUT (N) and the corresponding output control module, and a control terminal of the signal output reset module is connected with the reset signal input terminal RESET, for resetting the potential of output signal of the signal output terminal OUTPUT (N) under control of the reset signal inputted from the reset signal input terminal RESET (that is, the potential of the output signal of the signal output terminal OUTPUT (N) is pulled down to be at a low level), and in the present embodiment, the other terminal of the signal output reset module is connected with the low voltage signal VSS.

Since the shift register of the present embodiment has a plurality of signal output terminals, and has a plurality of signal output control modules and a plurality of signal output reset modules for controlling the signal output terminals to output signals, that is, each shift register of the present embodiment can drive a plurality of gate lines, thus when he shift register of the present embodiment is applied into a display panel, the number of the shift registers to be used in the display panel is reduced, so that the space to be occupied by the GOA circuit is further reduced, and a really narrow border design of a display apparatus can be achieved.

Preferably, as shown in FIG. 4, the gate driving signal generation unit of the shift register in the present embodiment further comprises a pull-down control module and a pull-down module. One terminal of the pull-down control module is connected with the pull-down node PD, and a control terminal of the pull-down control module is connected with a second clock signal input terminal CLKB, for controlling electric potential of the pull-down node PD in accordance with a second clock signal inputted from the second clock signal input terminal CLKB, and the pull-down node PD is a connection node between the pull-down control module and the pull-down module. The pull-down module is connected between the pull-down node PD and the pull-up control node PU, is turned on under control of the potential of the pull-up control node PU and is used for pulling down the potential of the pull-down node PD to be at a low level by connecting to the low voltage signal VSS to reduce the output noise at the pull-down node PD.

Further preferably, the shift register further comprises an input noise reduction module and a plurality of output noise reduction modules. The input noise reduction module is connected between the pull-up control node PU and the pull-down node PD, is turned on under control of the potential of the pull-down node PD and is used for reducing output noise at the pull-up control node PU by connecting to the low voltage signal VSS. One terminal of each of the output noise reduction modules is connected be' the corresponding signal output terminal OUTPUT (N) and the corresponding signal output control module, and a control terminal thereof is connected with the pull-down node PD, each of the output noise reduction modules is turned on under control of the potential of the pull-down node PD and is used for reducing output noise at the signal output terminal OUTPUT (N) connected thereto by connecting to the low voltage signal VSS.

In order to facilitate timing control, simple wiring, easy control, the shift register of the present embodiment comprises two signal output control modules, two signal output reset modules and two corresponding signal output terminals. That is to say, each shift register is used for driving two gate lines. Of course, the shift register of the present embodiment is not limited to a structure which only comprises two signal output control modules and two signal output reset modules, and the shift register of the present embodiment may also comprise three, four or more signal output control modules and signal output reset modules respectively, to drive the corresponding number of gate lines.

As above, the shift register of the present embodiment may drive a plurality of gate lines, thus a small number of shift registers may be used for driving gate lines of a display panel, so that the number of the shift registers used in the display panel is reduced, the space occupied by the GOA circuit is further reduced, and a really narrow border design of a display apparatus may be achieved.

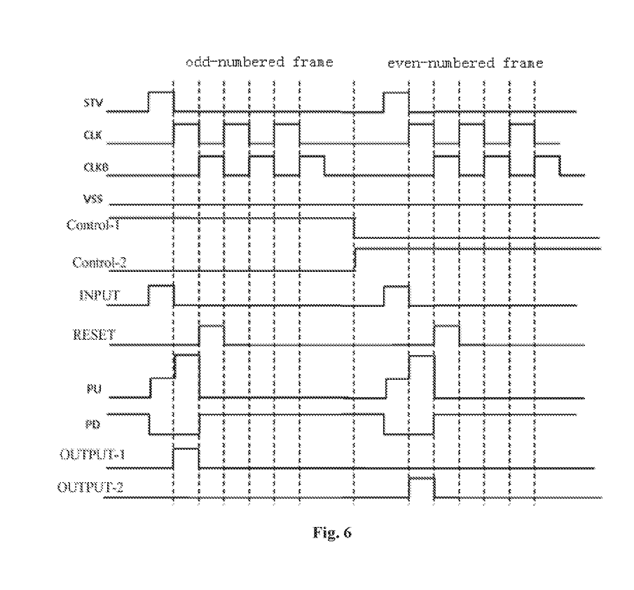

As a preferred mode of the present embodiment, as shown in FIG. 5, the input module comprises a first transistor M1, the input reset module comprises a second transistor M2, the pull-up module comprises a third transistor M3 and a storage capacitor C1, each of the signal output control modules comprises one switch transistor M12/M13, each of the signal output reset modules comprises one fourth transistor M4, the pull-down control module comprises a fifth transistor M5 and a ninth transistor M9, the pull-down module comprises a sixth transistor M6 and an eighth transistor M8, the input noise reduction module comprises a tenth transistor M10, each of the output noise reduction module comprises one eleventh transistor M11. The shift register is used for outputting two driving signals, that is, the connection relationships among the above devices are described by taking two signal output control modules, two signal output reset modules, two output noise reduction modules and two signal output terminals (OUTPUT-1, OUTPUT-2) as example.

Specifically, a first electrode and a control electrode of the first transistor M1 are connected with the signal input terminal INPUT of the shift register, a second electrode of the first transistor is connected with the pull-up control node PU. A first electrode of the second transistor M2 is connected with the pull-up control node PU, a second electrode of second transistor M2 is connected with the low voltage signal VSS, and a control electrode of the second transistor M2 is connected with the reset signal input terminal RESET. A first electrode of the third transistor M3 is connected with the first clock signal input terminal CLK, a second electrode of the third transistor M3 is connected with a second terminal of the storage capacitor C1 and the first electrodes of the switch transistors M12 and M13, a control electrode of the third transistor M3 is connected with the pull-up control node PU and a first terminal of the storage capacitor C1. The first electrodes of the two switch transistors (i.e., switch transistors M12 and M13) are connected with the second electrode of the third transistor M3, the second electrodes of the two switch transistors are respectively connected with the respective signal output terminals OUTPUT-1 and OUTPUT-2 (that is, the second electrode of the switch transistor M12 is connected with the signal output terminal OUTPUT-1, and the second electrode of the switch transistor M13 is connected with the signal output terminal OUTPUT-2), and are connected with the first electrodes of the fourth transistors M4 in the respective signal output reset modules, the control electrodes of the two switch transistors are respectively connected with the respective control signal input terminals Control-1 and Control-2 (that is, the control electrode of the switch transistor M12 is connected with the control signal input terminal Control-1, and the control electrode of the switch transistor M13 is connected with the control signal input terminal Control-2). The first electrodes of the fourth transistors M4 in the two signal output reset modules are respectively connected with the second electrodes of the switch transistors M12 and M13 in the respective signal output control modules, and are connected with the first electrodes of the eleventh transistors M11 in the respective output noise reduction modules, the second electrode of each fourth transistor M4 is connected with the low voltage signal VSS, and the control electrode of each fourth transistor M4 is connected with the reset signal input terminal RESET. A first electrode of the fifth transistor M5 and a first electrode and a control electrode of the ninth transistor M9 are connected with the second clock signal input terminal CLKB, a second electrode of the fifth transistor M5 is connected with the pull-down node PD, and a control electrode of the fifth transistor M5 is connected with a second electrode of the ninth transistor M9. A first electrode of the sixth transistor M6 is connected with the pull-down node PD, second electrodes of the sixth transistor M6 and the eighth transistor M8 are connected with the low voltage signal VSS, control electrodes of the sixth transistor M6 and the eighth transistor M8 are connected with the pull-up control node PU, a first electrode of the eighth transistor M8 is connected with the control electrode of the fifth transistor M5 and a second electrode of the ninth transistor M9. A first electrode of the tenth transistor M10 is connected with the pull-up control node PU, a second electrode of the tenth transistor M10 is connected with the low voltage signal VSS, and a control electrode of the tenth transistor M10 is connected with the pull-down node PD. The first electrodes of the eleventh transistors M11 in the two output noise reduction modules are connected with the second electrodes of the switch transistors M12 and M13 in the respective signal output control modules, the second electrode of each eleventh transistor M11 is connected with the low voltage signal VSS, and the control electrode of each eleventh transistor M11 is connected with the pull-down node PD.

Correspondingly, the present embodiment also provides a gate driving circuit comprising a plurality of above shift registers cascaded with each other, a signal outputted by the gate driving signal generation unit of the shift register of each stage is used as an input signal of the signal input terminal INPUT of the shift register of next stage, a signal outputted from each signal output terminal OUTPUT (N) of the shift register of each stage is used for driving one gate line. Thus, the gate driving circuit of the present embodiment has a simple structure and is easily achieved, the number of the shift registers used therein is reduced, thereby further reducing the occupied space of the GOA circuit, and when such a gate driving circuit is applied into a display apparatus, a really narrow border design of the display apparatus may be achieved.

Correspondingly, the present embodiment also provides a display apparatus comprising the gate driving circuit as above. The display apparatus may be any product or member with display function, such as phone, tablet computer, television, display, notebook computer, digital photo frame, navigator, etc.

Since the display apparatus of the present embodiment comprises the above gate driving circuit, a super narrow border design is achieved.

Of course, the display apparatus of the present embodiment may further comprise other conventional structures such as display driving unit. However, in order not to weaken understanding of inventive points of the present invention, the conventional structures will not be described herein.

Correspondingly, the present embodiment also provides a gate driving method comprising:
outputting a gate driving signal by a gate driving signal generation unit of a shift register in a gate driving circuit;
when a picture is to be displayed, outputting a plurality of gate driving signals from a plurality of signal output terminals of the shift register in a time-division manner by using respective signal output control modules connected to the signal output terminals, and resetting output signals of the signal output terminals by using respective signal output reset modules connected to the signal output terminals.

Preferably, the gate driving circuit comprises a plurality of shift registers cascaded with each other, and the gate driving method comprises driving one gate line by using a signal outputted from each signal output terminal of the shift register of each stage.

Specifically, the operational principle of the shift register in the gate driving circuit is described with reference to the timing diagram of FIG. 6.

First, it should be noted that, when a picture is displayed by using the shift register of the present embodiment, since the shift register for example has two output terminals, each shift register can provide scanning signals to two gate lines, wherein, when a first frame of picture is displayed, the signal output terminal connected with the signal output control module controlled by a first control signal input terminal Control-1 outputs signals, and at this time, the first frame of picture is defined as an odd-numbered frame of picture; when a second frame of picture is displayed, the signal output terminal connected with the signal output control module controlled by a second control signal input terminal Control-2 outputs signals, and at this time, the second frame of picture is defined as an even-numbered frame of picture. That is to say, the picture is composed of two frames, and the two signal output terminals of the shift register are used for displaying of different frames, and the specific descriptions are as follows.

When the odd-numbered frame of picture is displayed, the first signal output terminal OUTPUT-1 of the shift register outputs signals.

At a first time (initialization phase), a high level signal (or a frame gating signal STV) is inputted from the signal input terminal INPUT, at this time, the first transistor M1 is turned on, and the pull-up control node PU is charged.

At a second time, a high level signal is inputted from the first clock signal input terminal CLK, a high level signal is inputted from the first control signal input terminal Control-1, thus the switch transistor M12 controlled by the control signal input terminal Control-1 is turned on, and since the pull-up control node PU is charged at the first time and is at a high level, the third transistor M3 is turned on, the signal output terminal OUTPUT-1 outputs the high level signal, at the same time, due to bootstrap function of the storage capacitor, the potential of the pull-up control node PU is further pulled up, the sixth transistor M6 and the eighth transistor M8 are turned on, the pull-down node PD is pulled down to be at a low level, avoiding the influence of the signal inputted from the second signal input terminal INPUT on the signal outputted from the signal output terminal OUTPUT-1.

At a third time, the signal inputted from the first clock signal input terminal CLK becomes the low level signal, high level signals are inputted from the second clock signal input terminal CLKB and the reset: signal input terminal RESET, at this time, the ninth transistor M9 is turned on, the pull-down control node PD_CN is at the high level, thus the fifth transistor M5 is turned on, and the pull-down node PD is pulled up to be at the high level; at this time, the second transistor M2 and the fourth transistor M4 are turned on, the potential of the pull-up control node PU is pulled down to be at the low level, and the potential outputted from the first signal output terminal OUTPUT-1 is also pulled down to be at the low level, that is, the pull-up control node PU and the signal output terminal OUTPUT-1 are reset.

At a fourth time, a high level signal is inputted from the first clock signal input terminal CLK, a low voltage signal is inputted from the second clock signal input terminal CLKB, at this time, the potential of the pull-down node PD is maintained at the high level during the last phase, and thus the potential of the pull-up control node PU is still at the low level, at the same time, the tenth transistor M10 and the eleventh transistor M11 are turned on to reduce noise in the signal outputted from the pull-up control node PU and the signal output terminal OUTPUT-1, so that an error output is avoided. Therefore, the first signal output terminal OUTPUT-1 is maintained to output the low level signal until arrival of the next odd-numbered frame.

Similarly, after the odd-numbered frame is displayed, the even-numbered frame is started to be displayed, the display principle of the even-numbered frame is the same as that of the odd-numbered frame, but at this time, the signal output control module and the output reset module corresponding to the second signal output terminal OUTPUT-2 operate, which will not be described in detail herein.

It should be noted that, in the present embodiment, there also may be more signal output terminals OUTPUT (N), and all of the more signal output terminal OUTPUT (N) are used for displaying different frames of a single picture. The operational principle is the same as above, and will not be described in detail herein.

It should be understood that, the foregoing implementations are merely exemplary implementations for explaining the principle of the present invention, but the present invention is not limited thereto. Persons skilled in the art can make various variations and improvements without departing from the spirit and scope of the present invention, and these variations and improvements also fall within the protection scope of the present invention.

1. A shift register, comprising a gate driving signal generation unit for outputting a gate driving signal, wherein the shift register further comprises a plurality of signal output control modules, a plurality of signal output reset modules and a plurality of signal output terminals, and wherein
one terminal of each of the signal output control modules is connected with the gate driving signal generation unit and the other terminal thereof is connected with one corresponding signal output terminal, and each of the signal output control modules also has a respective control signal input terminal,
the gate driving signal outputted by the gate driving signal generation unit are outputted through the corresponding signal output terminal under control of a control signal inputted from the control signal input terminal, and
one terminal of each of the signal output reset modules is connected between the corresponding signal output control module and the corresponding signal output terminal for resetting output signal of the signal output terminal connected thereto.

2. The shift register of claim 1, further comprising a plurality of output noise reduction modules, wherein
one terminal of each of the output noise reduction modules is connected between the corresponding signal output control module and the corresponding signal output terminal for reducing noise of output signal of the signal output terminal connected thereto.

3. The shift register of claim 2, wherein each of the output noise reduction modules comprises one eleventh transistor,
a first electrode of the eleventh transistor is connected between the corresponding signal output control module and the corresponding signal output terminal, a second electrode of the eleventh transistor is connected with a low voltage signal, for reducing noise of output signal of the signal output terminal connected thereto by the low voltage signal.

4. The shift register of claim 1, wherein the gate driving signal generation unit comprises: an input module, a pull-up module, an input reset module, a pull-down control module, a pull-down module and an input noise reduction module, and wherein
the input module is connected between a signal input terminal and a pull-up control node of the shift register for controlling potential of the pull-up control node in accordance with a signal inputted from the signal input terminal, the pull-up control node is a connection node between the input module and the pull-up module,
the pull-up module is connected between the pull-up control node and the signal output control modules, a control terminal of the pull-up module is connected with a first clock signal input terminal for pulling up the gate driving signal to be outputted to the signal output terminal in accordance with the potential of the pull-up control node and a first clock signal inputted from the first clock signal input terminal,
one terminal of the input reset module is connected with the pull-up control node, and a control terminal of the input reset module is connected with a reset signal input terminal for pulling down and resetting the potential of the pull-up control node in accordance with a reset signal inputted from the reset signal input terminal,
one terminal of the pull-down control module is connected with the pull-down node, and a control terminal of the pull-down control module is connected with a second clock signal input terminal for controlling potential of the pull-down node in accordance with a second clock signal inputted from the second clock signal input terminal, the pull-down node is a connection node between the pull-down control module and the pull-down module,
the pull-down module is connected between the pull-down node and the pull-up control node for pulling down the potential of the pull-down node under control of potential of the pull-up control node, and
the input noise reduction module is connected between the pull-up control node and the pull-down node for reducing output noise at the pull-up control node under control of potential of the pull-down node.

5. The shift register of claim 4, wherein the input module comprises a first transistor, the input reset module comprises a second transistor, the pull-up module comprises a third transistor and a storage capacitor, the pull-down control module comprises a fifth transistor and a ninth transistor, the pull-down module comprises a sixth transistor and an eighth transistor, the input noise reduction module comprises a tenth transistor, and wherein
a first electrode and a control electrode of the first transistor are connected with the signal input terminal of the shift register, a second electrode of the first transistor is connected with the pull-up control node,
a first electrode of the second transistor is connected with the pull-up control node, a second electrode of the second transistor is connected with the low voltage signal, and a control electrode of the second transistor is connected with the reset signal input terminal,
a first electrode of the third transistor is connected with the first clock signal input terminal, a second electrode of the third transistor is connected with a second terminal of the storage capacitor and the signal output control modules, a control electrode of the third transistor is connected with the pull-up control node and a first terminal of the storage capacitor,
a first electrode of the fifth transistor and a first electrode and a control electrode of the ninth transistor are connected with the second clock signal input terminal, a second electrode of the fifth transistor is connected with the pull-down node, and a control electrode of the fifth transistor is connected with a second electrode of the ninth transistor,
a first electrode of the sixth transistor is connected with the pull-down node, second electrodes of the sixth transistor and the eighth transistor are connected with the low voltage signal, control electrodes of the sixth transistor and the eighth transistor are connected with the pull-up control node, a first electrode of the eighth transistor is connected with the control electrode of the fifth transistor and a second electrode of the ninth transistor,
a first electrode of the tenth transistor is connected with the pull-up control node, a second electrode of the tenth transistor is connected with the low voltage signal, and a control electrode of the tenth transistor is connected with the pull-down node.

6. The shift register of claim 1, wherein each of the signal output control modules comprises one switch transistor,
a first electrode of the switch transistor is connected with the gate driving signal generation unit, a second electrode of the switch transistor is connected with the corresponding signal output terminal and the corresponding signal output reset module, and a control electrode of the switch transistor is connected with the control signal input terminal.

7. The shift register of claim 1, wherein each of the signal output reset modules comprises one fourth transistor,
a first electrode of the fourth transistor is connected between the corresponding signal output control module and the corresponding signal output terminal, a second electrode of the fourth transistor is connected with the low voltage signal, and a control electrode of the fourth transistor is connected with the reset signal input terminal.

8. The shift register of claim 5, further comprising a plurality of output noise reduction modules, wherein each of the signal output control modules comprises one switch transistor, each of the signal output reset modules comprises one fourth transistor, and each of the output noise reduction modules comprises one eleventh transistor, wherein
a first electrode of the switch transistor is connected with the second terminal of the storage capacitor, a second electrode of the switch transistor is connected with the corresponding signal output terminal, and a control electrode of the switch transistor is connected with the corresponding control signal input terminal,
a first electrode of the fourth transistor is connected between the corresponding signal output terminal and the second electrode of the switch transistor, a second electrode of the fourth transistor is connected with the low voltage signal, and a control electrode of the fourth transistor is connected with the reset signal input terminal, and
a first electrode of the eleventh transistor is connected between the second electrode of the corresponding switch transistor and the corresponding signal output terminal, a second electrode of the eleventh transistor is connected with the low voltage signal, and the control electrode of the eleventh transistor is connected with the pull-down node.

9. The shift register of claim 1, wherein the shift register comprises two signal output control modules, two signal output reset modules and two signal output terminals.

10. A gate driving circuit, comprising a plurality of shift registers of claim 1, the shift registers being cascaded with each other, wherein
a signal outputted by the gate driving signal generation unit of the shift register of each stage is used as an input signal of the signal input terminal of the shift register of next stage,
a signal outputted from each signal output terminal of the shift register of each stage is used for driving one gate line.

11. A display apparatus, comprising the gate driving circuit of claim 10.

12. A gate driving method, comprising:
outputting a gate driving signal by a gate driving signal generation unit of a shift register in a gate driving circuit,
when a picture is to be displayed, outputting a plurality of gate driving signals from a plurality of signal output terminals of the shift register in a time-division manner by using respective signal output control modules connected to the signal output terminals, and resetting output signals of the signal output terminals by using respective signal output reset modules connected to the signal output terminals.

13. The gate driving method of claim 12, wherein the gate driving circuit comprises a plurality of shift registers cascaded with each other, and the gate driving method comprises driving one gate line by using a signal outputted from each signal output terminal of the shift register of each stage.
